(19) United States
(12) Patent Application Publication
(10) Pub. No.: US 2025/0044681 A1
(43) Pub. Date: Feb. 6, 2025

(54) IMPRINTING PROCESS

(71) Applicant: MORPHOTONICS HOLDING B.V., Veldhoven (NL)

(72) Inventors: Jan Matthijs TER MEULEN, Veldhoven (NL); Jules Theodorus Antonius KIERKELS, Veldhoven (NL); Bram Johannes TITULAER, Veldhoven (NL)

(21) Appl. No.: 18/710,156

(22) PCT Filed: Nov. 14, 2022
(86) PCT No.: PCT/EP2022/081817

§ 371 Date: May 14, 2024

(30) Foreign Application Priority Data
Nov. 15, 2021 (EP) 21208282.0

(51) Int. Cl. G03F 7/00

(52) U.S. Cl. CPC G03F 7/0002

(57) ABSTRACT

A roll-to-plate imprinting process is for the texturing of a substrate with a relief structure via a flexible stamp. The stamp includes at least one imprint texture. For carrying out the process, a resin or a lacquer is non-uniformly applied onto the substrate or onto the flexible stamp, or both, in an inhomogeneous pattern. The majority of the resin or lacquer is positioned on the flexible stamp at the leading edge side of the at least one imprint texture and/or the majority of the resin or lacquer is positioned on the substrate at the position of first contact with the stamp and/or at the leading edge sides of at least one active area.

The invention pertains to an imprinting process that applies a textured or patterned layer onto a substrate, which generally is named texturing or patterning of a substrate.

Functional textured layers on substrates play an important role in many fields of modern technology. The smart usage of such layers can enhance performance, reduce cost, or improve the visual appearance of the product. For example, diffusing layers are used in displays, enabling the use of thinner LED backlight concepts and illuminating the display from the sides. Other new high-tech possibilities are the integration of functional textured layers into solar panels improving their efficiency or integration in organic light-emitting diode (OLED) lighting panels to extract more light from microlenses for 3D optical applications.

For texturing, a substrate, a stamp, or both are coated with a lacquer (also called resin or resist—these three words will be used synonymously throughout this application). After pressing the stamp onto the substrate with lacquer in between, the textured lacquer is cured to a solid phase, while the stamp is still in contact with the lacquer. This process is typically called an imprinting process. Curing can be carried out thermally or by use of radiation such as visible light or UV light. Typically, texturing processes are classified into roll-to-roll processes, plate-to-plate processes, and roll-to-plate processes depending on whether the stamp is pressed onto the substrate by a roller such as in a rotatory printing press or by a plate such as an office stamp and depending on whether pressure is exerted to the substrate by a roller such as in a rotatory printing press or by a plate such as in a platen printing process.

Roll-to-plate imprinting has already been mentioned in U.S. Pat. No. 4,128,369.

Typically, roll-to-roll processes are used for imprinting large and flexible substrates such as printing of newspapers while plate-to-plate imprinting is typically carried out for small substrates such as for the printing of electronic circuits.

Roll-to-plate imprinting is a technique which is typically used for imprinting large and rigid substrates such as glass or metal plates used in producing displays, solar cells or other optoelectronic devices. In roll-to-plate imprinting typically either a textured roller or a flexible stamp is used. Said flexible stamp is then not necessarily a part of the roller but is pressed onto the substrate by a roller. The advantage of the latter is that pressure does not have to be exerted on the whole substrate at the same time, but can be exerted in a line and that the design of the texture to be imprinted can be longer than the circumference of the roller. In roll-to-plate imprinting, typically rigid substrates are provided on a conveyor belt or on a series of conveying rollers and are conveyed underneath the imprinting roller with, depending on the embodiment, optionally a flexible stamp in between. Prior to the imprinting process either the substrate or the stamp or both components are covered with imprintable resin or lacquer which upon contact with the substrate or stamp is textured with a negative imprint of the texture of the stamp and cured typically while in contact with the stamp in order to properly conserve the imprinted texture of the resin. After curing, the stamp is separated from the imprinted layer of cured resin or lacquer on the substrate. There is the risk that, during the imprinting process, when there is contact of the resin or lacquer with the stamp and/or the substrate, substantial amounts of lacquer are squeezed off the substrate or to unwanted locations on the substrate leading to a big variety of problems. First, the spilt lacquer soils the apparatus wherein the imprinting process is carried out, second the overflow of lacquer can contaminate the backside of the product, third it adversely effects the quality of the imprinting product as it can lead to an uncontrolled, non-uniform flow of lacquer between the substrate and the stamp. This overflow of lacquer as well as air enclosures between the substrate and the stamp are typically handled by modifications of the stamp as described e.g. in EP3256907 and EP3256906. However, solutions proposed therein do not solve the problem of soiling of the apparatus by spilt lacquer which leads to additional cleaning effort and also to waste of lacquer which is detrimental for both economy and ecology of the imprinting process. The problem is typically solved by reserving space for a larger overflow area outside of the active area whereby the active area is the region of the substrate which is to be textured or patterned by the imprinting process. Such larger overflow area outside of the active area adds to the waste of substrate materials and lacquer and for this reason increases the costs of the process.

It is thus the goal of the present application to provide a roll-to-plate imprinting process which is both more economic and which saves resources by a reduced demand of lacquer.

The problem is solved by a roll-to-plate imprinting process for the texturing of a substrate with a relief structure via a flexible stamp comprising at least one imprint texture, whereby a resin or a lacquer is non-uniformly applied onto the substrate or onto the flexible stamp, or both, in an inhomogeneous pattern, whereby the majority of the resin or lacquer is positioned on the flexible stamp at the leading edge side of the at least one imprint texture and/or that the majority of the resin or lacquer is positioned on the substrate at the position of first contact with said stamp and/or at the leading edge sides of at least one active area.

In the context of the present application, the term “predominantly” indicates that more than 50%, in an embodiment more than 80%, of the amount of resin or lacquer is meant.

The majority of the resin is positioned at the substrate at or around the location of first contact with the stamp or around the active area at one or more leading edges of the one or more active areas, i.e. in front and/or aside of the one or more active areas as seen in the direction of the imprinting process. Additionally or alternatively, the majority of the resin is positioned at the stamp at or around the location of first contact with the substrate or at or around the leading edge of an imprint texture of the stamp.

Positioning of the resin is carried out prior to the imprinting process. An active area on the substrate is the location at which the resin is to be imprinted to create the relief structure. It is noted that on one substrate there may be several active areas, e.g. if multiple products are placed on one stamp. Over a large substrate, the pattern in which the resin is placed on the substrate and/or on the flexible stamp may be repetitive if repetition if over different active areas.

A roll-to-plate imprinting process according to the present application is an imprinting process wherein a roller exerts pressure onto an imprinting texture which is imprinted to a discrete plate-like substrate, wherein the substrate moves relative to the roller. In roll-to-plate imprinting, pressure is exerted not to the whole substrate at the same time but in a line-shaped area perpendicular to the direction in which the substrate moves relative to the roller. The direction in which the substrate is moves relative to the roller is called “direction of the imprinting process” or “imprinting direction” throughout this application. The presence of an imprint direction is a key feature which distinguishes roll-to-plate (and roll-to-roll) imprinting processes from plate-to-plate imprinting processes wherein pressure is exerted to the entire active area at the same time like in a traditional platen printing press. In alternative plate-to-plate processes the pressure is built up circularly from the inside to the outside. Plate-to-plate processes thus do not have a unidirectional imprinting direction, while roll-to-roll imprinting processes and roll-to-plate imprinting processes do have a unidirectional imprinting direction, which is the direction of the imprinting process.

In contrast to the continuous roll-to-roll process, the roll-to-plate process imprints discrete panels with a start and a stop, usually near or at the edges of a discrete substrate. Therefore, the effects of start and stop such as resin spilling due to resin overflow are potentially present on each substrate and not, as e.g. in roll-to-roll imprinting only at the edges of a very long web-like substrate where they can be just cut off and disposed with negligible impact on the economy of the process. In order to achieve a constant and high quality of imprinting, the overflow of resin thus has to be precisely controlled to avoid overflow of resin in this roll-to-plate process.

Throughout the present application, texturing means a process wherein a substrate, which has a smooth surface, is provided with a three-dimensional structure which, in view from above, looks like a relief of valleys and hills or of openings or depressions and elevations of variable height and depth and size. In an embodiment, texturing can mean that a layer of resin on a substrate is provided with a three-dimensional structure.

According to the application, a stamp is any means that may be used to transfer a negative of a a texture onto a surface of e.g. a resin layer and which for this purpose has a three-dimensional texture which in the following will be called “imprint texture”. The imprint texture typically consists of openings or depressions and elevations and the stamp may have antistick functionality which makes it easier to remove a stamp from cured resin. A stamp may work according to two fundamental principles.

First, the principle of relief imprinting where the stamp is wetted with any kind of imprinting medium such as ink, wax, resin or lacquer at its elevations only. After wetting with the imprinting medium, the stamp is pressed onto the substrate where it leaves an image of its elevations. In relief imprinting, which is e.g. the working principle of a regular office stamp, only elevations are wetted with imprinting medium and the openings or depressions have the purpose of separating the elevations from each other.

Second, the principle of intaglio imprinting where the stamp is wetted with imprinting medium and afterwards treated with a washer or a doctor blade in such a way that the imprinting medium only remains in the openings while the elevations are free of imprinting medium. The stamp is then pressed on the substrate where it leaves an image of its openings which are formed as elevations either within the resin or on the substrate with the resin being pushed away either entirely or in part. The stamp may also be a thin metal sheet, or a thin glass sheet or a combination of one or more foils and/or metal sheet(s) and/or glass sheet(s). Thus, in intaglio imprinting the purpose of the elevations is to separate the openings from each other. The principle of intaglio imprinting may also be used to texture an imprinting medium, like lacquer or imprint resin, which is already present on the substrate. In such case, elevations in the stamp are transferred into openings on the substrate while openings in the stamp are transferred into elevations on the substrate which is known from the mode of operation of a traditional seal matrix which is used to texture a spot of molten wax.

Stamps may be either rigid or flexible. According to the present application, a flexible stamp is a stamp which has a Young's modulus of at most 10 Giga Pascal (GPa).

The flexible stamp of the pending application may be a plastic foil e.g. such as, but not limited to, polyethylene terephthalate (PET) or polyethylene naphthalate (PEN), polycarbonate (PC). The flexible stamp may also be a metal sheet, glass sheet or any other sheet or a combination or laminate of a plurality of materials The foil or sheet may be textured by itself or the foil or sheet may serve as a carrier of an imprint texture which consists of a distinct layer or layers. In an embodiment, the imprint texture may comprise a polymer comprising monomeric, oligomeric or polymeric components such as epoxides, thiols, polyvinyl resins, acrylates, methacrylates, polyethers, vinylethers, urethane acrylates, polyesters, fluorinated acrylates, fluorinated methacrylates, fluorinated polyethers, siloxanes, siloxane-acrylates, or blends thereof. The imprinting texture may have intrinsic antistick properties. The antistick properties may be achieved by by additives to the materials to decrease the surface free energy or by the right combination of low surface free energy materials (as example, among others perfluorpolyether (PFPE) monomers, perfluorinated monomers, silicone monomers, and/or aliphatic monomers) or by surface treatment such as anti-stick coatings.

The imprinting medium according to the pending application may be a lacquer or a resin. Typical imprinting media used in the pending application are curable resins or lacquers which are liquid or viscous when applied onto the substrate and when contacted with the flexible stamp and which can be cured by exposure to heat or radiation such as UV radiation. If radiation is to be used for curing then either the stamp or the substrate or both should be transparent for said radiation. In an embodiment, the imprinting medium may be a polymer comprising monomeric, oligomeric or polymeric components such as: epoxides, thiols, polyvinyl resins, acrylates, methacrylates, polyethers, vinylethers, urethane acrylates, polyesters, fluorinated acrylates, fluorinated methacrylates, fluorinated polyethers, siloxanes, siloxane-acrylates or blends thereof. In an embodiment, the resin may comprise agents for initiating the curing such as radical, cationic or anionic initiators. Suitable initiators are known by a person skilled in the art. Possible radical initiators are azo compounds such as azobisisobutyronitrile, peroxides such as dibenzoylperoxide or peroxodisulfate, phosphine oxides such as, diphenylphosphine oxide, aromatic ketones such as 1-hydroxy-cyclohexylphenyl-ketone or 2-hydroxy-2-methylpropiophenone, or a norrish type II initiator such as methylbenzoylformate. Possible cationic and anionic initiators are benzenesulfonic acid esters, alkylsulfonium salts or photo base generators such as triphenylsulfonium (cationic), tetrafluoroborate or 2-nitrobenzyl cyclohexylcarbamate (anionic).

Throughout the present application, the term “nonuniform” means that the amount of a substance such as a resin or lacquer which is applied to a surface is not the same in all parts of the surface but that there is a gradient in the amount of substance on the surface or simply that the substance is not equally distributed over the surface. In an embodiment, said gradient is parallel to the imprinting direction, antiparallel to the imprinting direction, perpendicular to the imprinting direction, or oriented at any angle between −90 and +90 degrees with respect to the imprinting direction. In accordance with the mathematical definition of the gradient, the direction of the gradient is the direction in which the amount is decreasing. In an embodiment, “non-uniform” means that more than 50% of the resin or lacquer is located in one half of the active area of the substrate and/or on the imprint texture of the flexible stamp. In an embodiment, “non-uniform” means that more than 70% of the resin or lacquer is located in one half of the active area of the substrate and/or on the imprint texture of the flexible stamp. In an embodiment, “non-uniform” means that more than 85% of the resin or lacquer is located in one half of the active area of the substrate and/or on the imprint texture of the flexible stamp. In an embodiment, said half of the active area of the substrate and/or the imprint texture of the flexible stamp, containing the resin, may be the first half seen in the direction of the imprinting process.

An example for a nonuniform layer is a resin layer which increases or decreases in thickness in the imprinting direction or a substrate on which certain patterns of resin are formed. Non-uniform may also mean that in certain parts of the substrate no resin is present while in other parts of the substrate resin is present.

The term “inhomogeneous” means that a substance such as a resin or lacquer which is applied to a surface is not evenly distributed over the entire surface and that a pattern is not the same in all parts of a surface which means that a pattern is e.g. not repeating over the whole surface. Examples for inhomogeneous patterns according to this definition are e.g. comb-like patterns or patterns in the form of similar to single letters such as “E”, “M” or “W” which are formed by the resin or lacquer on the surface. A typical feature of an inhomogeneous pattern is that it both contains regions wherein the surface is covered by resin or lacquer and regions wherein the surface is not covered by resin or lacquer. Furthermore, typically, inhomogeneous patterns are not repeated within or around a single active area surface. It can be repeated having multiple active areas on one larger imprint surface. The resin or lacquer may be applied on the substrate in a manner of a closed line or closed area (as example oval, rectangular or any area shape) or as a dotted pattern of e.g. droplets. Furthermore, not the full surface of a substrate or stamp needs to be covered by resin or lacquer.

A closed layer according to the present application is a layer wherein the whole surface of the substrate or stamp or at least the whole active area of the substrate or entire textured area of a stamp is covered by resin or lacquer.

The inhomogeneous pattern may comprise one or more sub-patterns which sub-patterns are separated from each other such as several comb-like patterns or patterns in the form of, or similar to single letters such a “E”, “M”, “W”, or the number “3”.

A substrate according to the application is a plate-like body, i.e. a body wherein the length and the width are both by a factor of at least 4 larger than its thickness.

The substrate according to the application is rigid which means that its Young's modulus is at least 0.5 GPa. The substrate may be of any material that fulfils the criterion of rigidity such as polymer sheets of e.g. polymethyl methacrylate (PMMA) or polycarbonate, glass, metal such as copper, steel, or aluminium or ceramics or compound materials or laminates made thereof.

The substrate used in a process according to the application is typically a discrete substrate.

The substrate used in a process according to the application may comprise several discrete substrates which prior to being provided to the process can be connected in such a manner that they can be provided to the process as one unit such as by having been glued together or having been arranged in a suitable frame or on a suitable tray or carrier.

The substrate according to the application has an active area which is the area which will be imprinted during the imprinting process. Typically, the active area is located close to the center of the substrate and thus is separate or even distant from the edges of the substrate by regions which are not part of the active area which will be called “non-active regions” in the following. The non-active regions enable a smooth start of the imprint process and might serve as an area that intercepts excessive amounts of resin such that resin overflow will not contaminate the edges of the substrate or flexible stamp or rollers. The non-active regions can be of varying size (typically, from hundreds of microns up to several centimeters or larger). The active area on the substrate can have the same surface area as the imprint texture of the flexible stamp, but it can also have a different surface area.

A pattern according to the application is any kind of distribution of resin or lacquer on either the substrate and/or the flexible stamp that contains both regions which are covered by resin or lacquer and regions which are not covered by resin or lacquer. Said pattern does not need to have any aesthetic or graphical meaning for being called a pattern. However, it can be a regular pattern which means that it is a clearly reproducible distribution of resin on different substrates and/or flexible stamps such as e.g. a comb-like shape, a shape of one or more straight, bended and/or crossed lines, or the shape of an inverted letter “E” or similar shape. The pattern may also be a random distribution of e.g. randomly oriented lines comparable to a plate of spaghetti or a distribution of randomly located and/or randomly sized droplets.

A pattern comprised of some or many droplets may be randomly located and/or randomly sized, and could also be comprised totally or in part of regularly spaced droplets.

The pattern may further be either a continuous or a discontinuous pattern. In a continuous pattern, the regions which are covered with resin or lacquer are connected to each other. In a discontinuous pattern, regions which are covered by lacquer and/or resin are separate from each other and thus have the character of islands within a region which is not covered by resin or lacquer.

The pattern may be located on a coating area on the flexible stamp and/or the substrate. It is important to notice that the coating area neither has to be identical with the imprint texture on the flexible stamp nor with the active area on the substrate. However, the coating area may be located completely within or in part within the active area on the substrate and/or on the imprint texture on the flexible stamp. The coating area may be located completely outside or in part outside the imprint texture on the flexible stamp and/or the active area on the substrate. In such cases, the coating area is located predominantly in front of the active area and/or the imprint texture seen in the imprinting direction.

In an embodiment, the coating area comprises less than 50% of the surface area of the active area. In an embodiment, the coating area comprises less than 30% of the active area. Note that the coating area may completely be located outside or in part be located outside, or totally be inside the active area of the substrate and/or the imprint texture of the flexible stamp. Note that the coating area is not only the area covered by resin or lacquer but the area which is bordered by the envelope of all regions which are covered by resin or lacquer. The coating area thus comprises all areas covered by resin or lacquer but also comprises areas which are not covered by resin or lacquer.

When starting the imprinting process on a new substrate, a leading edge on the flexible stamp and a leading edge on the substrate are brought in contact with each other. The leading edge on the flexible stamp may be part of the imprinting texture or it may be located in front of the imprinting texture seen in the direction of the imprinting process. The leading edge on the substrate may be part of the active area or it may be located in front of the active area seen in the direction of the imprinting process. The leading edge on the substrate and/or on the flexible stamp is either part of the coating area or located in front of the coating area seen in the direction of the imprinting process. After the leading edge of the flexible stamp and the leading edge of the substrate have been brought in contact to each other, the imprinting process proceeds in the imprinting direction with the area of contact between the flexible stamp and the substrate also proceeding in imprinting direction. While proceeding in the imprinting direction, resin or lacquer is distributed or redistributed in the active area in the imprint direction by spreading the inhomogeneous pattern of resin or lacquer and forming a front of resin or lacquer which moves in the direction of the imprint. Distribution of the resin or lacquer is carried out in a continuous process before or at the same time the imprint texture is transferred into the resin or lacquer by the flexible stamp in the active area. A continuous process according to the present application is a process wherein there is no sharp difference between two different process steps such as the distribution of the lacquer and the transfer of the imprinting texture into the lacquer. This may e.g. mean that while a distributing part of the flexible stamp distributes the resin or lacquer on the surface in the direction of the imprint process, an imprinting part of the flexible stamp at the same time transfers a part of the imprinting texture into the distributed lacquer whereby there is no sharp difference between the distributing part and the imprinting part.

Upon contact between the flexible stamp and the substrate, the inhomogeneous pattern of resin or lacquer on the stamp and/or the substrate is thus transformed into an imprinted layer of resin or lacquer which is textured in the active area.

In an embodiment, the resin or lacquer covers at least 40% of the surface area of the substrate after the imprinting process. In an embodiment, the resin or lacquer covers at least 50, 60, 80 or 90% of the surface area of the substrate after the imprinting process. This prevents soiling by and overflow of the resin in the imprinting process.

Important factors for the control of the distribution or redistribution of the resin or lacquer during imprinting are the size of the gap between the flexible stamp and the substrate as well as the pressure by which the flexible stamp and substrate is brought together. The smaller the gap or the higher the pressure is, the more will the resin or lacquer be spread when brought in contact with the flexible stamp.

In an embodiment, the distributed resin or lacquer covers at least two separate regions on the active area of the substrate which are separated from each other by regions which are not covered by resin or lacquer which means that the resin or lacquer forms at least two islands on the active area of the substrate.

In a further embodiment the two or more islands of resin remain separated after imprinting and curing of the resin, replicating two or more separated active areas on one or more substrates.

In an embodiment, after the imprinting process, the substrate has at least one open area which is free of resin or lacquer. Said open area is located outside the active area.

The application further pertains to an imprinted substrate which is obtained according to the process according to the application.

The application further pertains to an apparatus for carrying out a roll-to-plate imprinting process according to the application.

The apparatus according to the application comprises at least one resin or lacquer application device, whereby at least one application device comprises at least one resin or lacquer reservoir, at least one distributing means for applying the resin or lacquer and at least one monitoring and control device, whereby the at least one application device is movably arranged at least in the coating area of the substrate or flexible stamp, whereby the distributing means can apply the resin or the lacquer in a pattern in the coating area while the control device controls the application of resin or lacquer.

The resin or lacquer application device may comprise at least one dispenser, at least one kiss roll, at least one spray head and/or at least one stamp as distribution means. At least one of said distribution means is movably arranged in any manner which is known to the person skilled in the art such as e.g. on an arm of a robot such as a delta robot, on a movable stage, movable on a rail or in any combination thereof. As an example, the lacquer application device may work according to the same principle as an inkjet printer which distributes ink droplets on a substrate which is conveyed underneath a printing head which is movable in a direction perpendicular to the conveying direction of the paper.

The apparatus according to the application further comprises a monitoring and control device which is able to control the amount and/or the position of resin or lacquer before or after imprinting. The monitoring and control device may monitor and control the amount and/or the position of resin or lacquer by weight, the distance between stamp and substrate, pressure, optically or by means of any other kind of electromagnetic radiation such as microwaves, infrared light or UV light. Consequently, the monitoring and control device may be a camera, an infrared sensor, a weighing scale, a microwave detector, a laser unit or any combination thereof. The monitoring and control device may be part of a feedback loop together with the resin or lacquer application device in such a manner that the process of applying resin or lacquer is monitored and controlled by the monitoring and control device. As a part of said feedback loop, the distance, pressure, and imprint speed between the flexible stamp and the substrate may be controlled, whereby the distance depends on the desired distribution of the resin or lacquer on the application area.

### FIGURES

FIG. 1 shows a schematic roll-to-plate imprint process. The flexible stamp 100 with openings & elevations 100B is pressed, by use of the roller 101, on the resin 102, present on substrate 104. Due to the unidirectional imprint direction, as shown by the arrow, a resin front 102B is created. The substrate has a leading edge 104A and trailing edge 104B, determined by the imprint direction. The detector 105 can monitor resin flow and/or the amount and/or the position of resin.

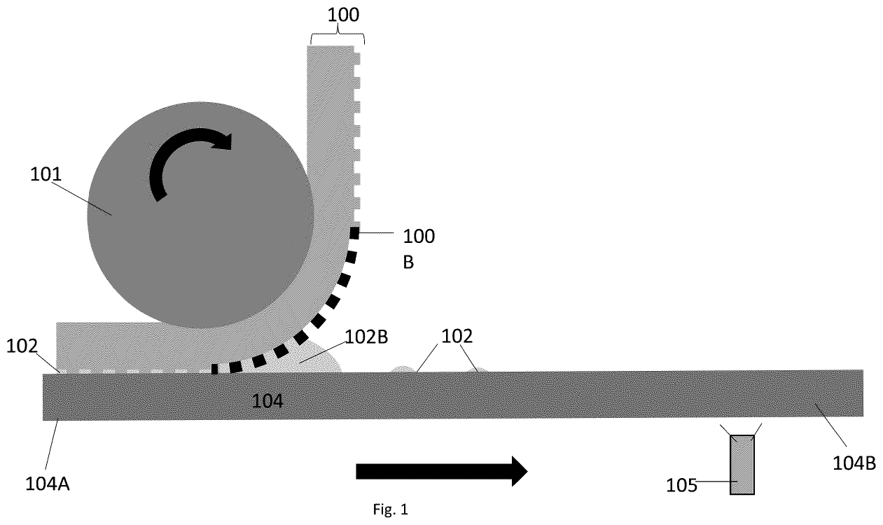

FIG. 2 shows a variety of patterns 202 deposited on the substrate 104 before imprinting (FIGS. 2a, 2c and 2e) and after imprinting (FIGS. 2b, 2d and 2f). On the substrate there is a preferred imprint area 201. This is the position where the active area will be positioned after imprinting, therefore also called active area 201. By imprinting, resin is spread out into resin layer 203, due to the contact of the flexible stamp with the substrate. The shape of the resin layer 203 after the roll-to-plate imprint process depends on the pattern 202 and the imprint settings and can therefore be controlled by control loops. In FIG. 2a, the pattern 202 is a continuous line, located inside the active area 201. In FIG. 2c the pattern 202 is formed by a discontinuous line and droplets outside the active area 201. In FIG. 2e the pattern 202 is two islands of resin partly inside and partly outside the active area 201. For each of the patterns 202, more than 50% of the amount of resin is located on the leading half of the active area 201A, positioned on the leading side of the substrate 104A, and less than 50% placed on the trailing half of the active area 201B. In FIG. 2a and FIG. 2e the pattern 202 is 100% placed on the leading half of the active area 201A. In FIG. 2c the pattern 202 extends into the trailing area of the active area 201B. But the majority of the amount of resin is located on the leading half of the active area; at least more than 50%. The leading and trailing sides are determined by the imprint direction, indicated by the arrow. FIG. 2f shows the situation where after the imprint process, two separate active areas 201 are imprinted with two separate resin layers 203.

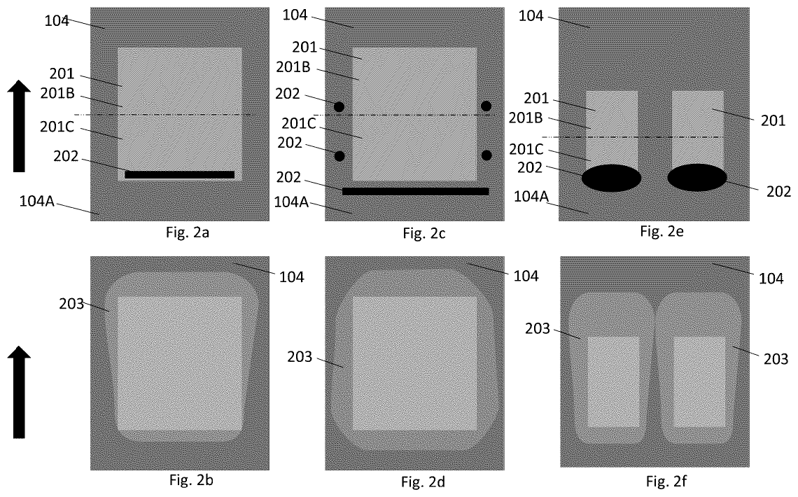

FIG. 3 shows the distribution of a pattern comprising droples of resin to a closed layer of resin or lacquer on a substrate surface after imprinting. In FIG. 3a) pattern 301 on a surface 104 is shown. In one embodiment, the droplet size in one row can vary, whereby preferably the droplet size is smaller close to the trailing edge. In a further embodiment, the droplets can be random or irregular in location and size. FIG. 3b) shows the closed layer of resin or lacquer 302 which has been formed from the resin droplets in 301 on the surface 104 by contact with a flexible stamp with a higher applied pressure. FIG. 3c) shows the closed layer of resin or lacquer 303 formed from the pattern 301 on the surface 104 by contact with a flexible stamp at an even higher applied pressure. The closed layer 303 is remarkably larger than the closed layer 302. The imprint directions are shown with an arrow.

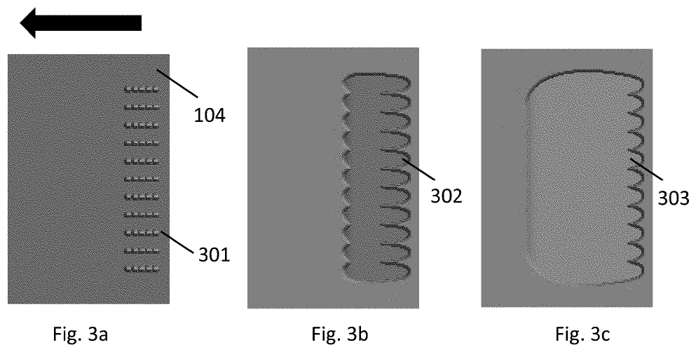

FIG. 4 shows the distribution of a discontinuous pattern on a surface 104 using a pattern with droplets and lines. In FIG. 4a), the discontinuous pattern of resin or lacquer 401 is shown. FIG. 2b) shows a closed layer of resin or lacquer 402 which is obtained by contact of the discontinuous pattern 201 with a flexible stamp in the roll-to-plate imprint process.

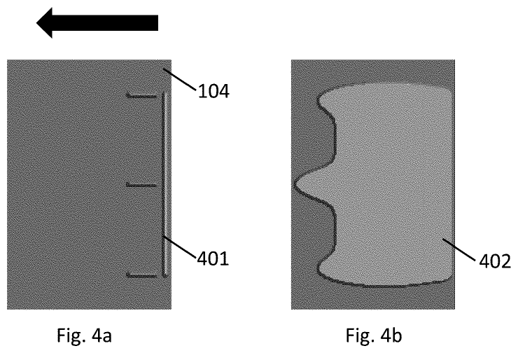

1. A roll-to-plate imprinting process for texturing of a substrate with a relief structure via a flexible stamp comprising at least one imprint texture, wherein a resin or a lacquer is non-uniformly applied onto the substrate or onto the flexible stamp, or both, in an inhomogeneous pattern, wherein a majority of the resin or lacquer is positioned on the flexible stamp at a leading edge side of the at least one imprint texture and/or that the majority of the resin or lacquer is positioned on the substrate at a position of first contact with said stamp and/or at leading edge sides of at least one active area.

2. The roll-to-plate imprinting process according to claim 1, wherein the resin is applied in a coating area prior to imprinting, wherein a surface area of the coating area comprises less than 50% of a surface area of the substrate.

3. The roll-to-plate imprinting process according to claim 1, wherein a coating area is part of the at least one active area and/or the coating area is positioned outside or partially outside of the at least one active area.

4. The roll-to-plate imprinting process according claim 1, wherein the pattern comprises droplets and/or comprises of one or more closed lines.

5. The roll-to-plate imprinting process according to claim 1, whereby the pattern is a discontinuous pattern.

6. The roll-to-plate imprinting process according to claim 1, wherein the pattern at least partially comprises a random distribution of resin.

7. The roll-to-plate imprinting process according to claim 1, wherein in a continuous imprinting process the resin or lacquer is distributed over the at least one active area before or at a same time as the imprint texture is imprinted into the resin or lacquer in the at least one active area.

8. The roll-to-plate imprinting process according to claim 1, wherein the distributed resin or lacquer covers at least 70% of a surface area of the substrate after imprinting.

9. The roll-to-plate imprinting process according to claim 1, wherein the substrate has at least one open area after the imprinting process which is free of resin or lacquer.

10. The roll-to-plate imprint process according to claim 1, wherein the distributed resin or lacquer covers at least two separate regions on the substrate which are separated from each other by regions which remain uncovered with resin or lacquer after the imprinting and curing of the resin or lacquer, providing two or more separate active areas on the substrate.

11. An imprinted substrate obtained by a process according to claim 1.

12. An apparatus for a roll-to-plate imprinting process according to claim 1, wherein the apparatus comprises at least one resin or lacquer application device, wherein at least one application device comprises at least one resin or lacquer reservoir, at least one distributor for applying the resin or lacquer and at least one monitoring and control device, wherein the at least one distributor is movably arranged to apply resin in at least in the coating area of the substrate, wherein the distributor is configured to apply the resin or the lacquer in a pattern in the coating area while the control device controls application of resin or lacquer.

13. The apparatus according to claim 12, wherein the monitoring and control device monitors and controls weight values, and/or distance values between stamp and substrate, pressure values, and/or imprint speed values, and/or resin position during the imprinting process.

14. The apparatus according to claim 13, wherein the monitoring and control device adjusts applied resin volume and/or distance between the flexible stamp and the substrate, and/or pressure, and/or imprint speed, wherein the adjustments depend on desired distribution of the resin or lacquer on the application area after imprinting.

15. The roll-to-plate imprinting process according to claim 1, wherein the resin is applied in a coating area prior to imprinting, wherein a surface area of the coating area comprises less than 30% of a surface area of the substrate.
